(19) United States
(12) Patent Application Publication
(10) Pub. No.: US 2011/0300815 A1
(43) Pub. Date: Dec. 8, 2011

(54) INTEGRAL LATCH MECHANISMS FOR MOUNTING ELECTRONICS MODULES

(75) Inventors: Kevin Thompson, Chaska, MN (US); Michael J. Nelson, Prior Lake, MN (US); Michael J. Wayman, Waconia, MN (US)

(73) Assignee: ADC TELECOMMUNICATIONS, INC., Eden Prairie, MN (US)

(21) Appl. No.: 12/796,280

(22) Filed: Jun. 8, 2010

(51) Int. Cl. H04B 1/38; H05K 7/20

(52) U.S. Cl. 455/90.3; 361/715

(57) ABSTRACT

In one embodiment, a locking mechanism comprises: a lever-arm-component coupled to a first side of an module and a second side of the module that opposes the first side; the lever-arm-component rotates about a first axis; first and second latching-arm-components including latching-hooks, the first latching-arm-component coupled to the lever-arm-component on the first side and rotating about a second axis that run parallel to and offset from the first axis; the second latching-arm-component coupled to the lever-arm-component on the second side and rotating about the second axis; and a secondary fastener. The first and second axes are oriented in an over-center configuration such that when the lever-arm-component is rotated about the first axis from a first to second position, the second axis will pass through a locking axis and the latching-hooks apply a force against a mechanism of the enclosure that presses the module against a heat sink of the enclosure.

### BACKGROUND

In the field of telecommunications, there is a trend to reduce both the size and the expenses associated with infrastructure equipment. The result is a demand on telecommunications infrastructure equipment providers to manufacture smaller equipment that can be operated and maintained in a more cost effective manner, while retaining all the functionality of legacy equipment. The modularity of designs proposed for such equipment, along with the desire of equipment operators to be able to quickly change out modular components with minimal impact on service availability, has introduced new thermal management challenges for dissipating heat generated by telecommunications infrastructure equipment.

For the reasons stated above and for other reasons stated below which will become apparent to those skilled in the art upon reading and understanding the specification, there is a need in the art for improved systems for modular equipment mounting in telecommunications system.

### SUMMARY

The Embodiments of the present invention provide methods and systems for cooling electronics equipment enclosures, and will be understood by reading and studying the following specification.

In one embodiment, a locking mechanism for securing a module within an electronics enclosure comprises: a lever arm component rotatably coupled to a first side of an electronics module and a second side of the electronics module that opposes the first side, wherein the lever arm component rotates about a first axis that passes through the electronics module; a first latching arm component including a first latching hook, the first latching arm component rotatably coupled to the lever arm component on the first side of the electronics module, wherein the first latching arm component rotates about a second axis that run parallel to and offset from the first axis; a second latching arm component including a second latching hook, the second latching arm component rotatably coupled to the lever arm component on the second side of the electronics module, wherein the second latching arm component rotates about the second axis that runs parallel to and offset from the first axis; and at least one secondary fastener coupled to the electronics module. The first axis and second axis are oriented in an over-center configuration such that when the lever arm component is rotated about the first axis from a first position to a second position, the second axis will pass through a locking axis. When the lever arm component is rotated about the first axis from the first position to the second position, the first latching hook and the second latching hook apply a force against at least a first hook mechanism of the electronics enclosure that presses the electronics module against a heat sink of the electronics enclosure.

### BRIEF DESCRIPTION OF THE DRAWINGS

Embodiments of the present invention can be more easily understood and further advantages and uses thereof more readily apparent, when considered in view of the description of the preferred embodiments and the following figures in which:

FIGS. 1A and 1B are diagrams illustrating two sides of an electronics module having a mounting mechanism of one embodiment of the present invention;

FIG. 1C is a close-up detail of the mounting mechanism of one embodiment of the present invention;

FIG. 2 illustrates an electronics enclosure for housing the electronics module of FIGS. 1A and 1B; and

FIG. 3 is a diagram illustrating of an electronics module with a mounting mechanism in its fully engaged position.

In accordance with common practice, the various described features are not drawn to scale but are drawn to emphasize features relevant to the present invention. Reference characters denote like elements throughout figures and text.

### DETAILED DESCRIPTION

In the following detailed description, reference is made to the accompanying drawings that form a part hereof, and in which is shown by way of specific illustrative embodiments in which the invention may be practiced. These embodiments are described in sufficient detail to enable those skilled in the art to practice the invention, and it is to be understood that other embodiments may be utilized and that logical, mechanical and electrical changes may be made without departing from the scope of the present invention. The following detailed description is, therefore, not to be taken in a limiting sense.

This disclosure describes improved systems for modular equipment mounting in telecommunications system. Embodiments of the present invention described herein provide means for removing heat from modularized telecommunications electronics, particularly modules comprising high power amplifiers used in wireless telecommunications, while also providing a means for quickly and securely mounting such modules within an electronics enclosure. Further, one or more embodiments of the present invention described herein further provide means that assist a technicians in carrying and handling such modules during the installation or removal process.

Solutions provided by embodiments of the present invention provide a mounting mechanism in the form of a lever arm component of an electronics module that is designed to provide a force onto a hook feature that secures a heat transferring surface of the electronics module to a heat sink feature of an electronics enclosure that houses the electronics module. The lever arm component provides a means for amplifying the force exerted by the technician when latching the electronics module to the heat sink, increasing the force that holds the electronics module to the heat sink to provide for a correspondingly better thermal connection between the two, thus improving thermal performance. The lever arm components further spans the width of the module and to serve as a handle that provides a gripping point for the module. Once installed into the electronics enclosure the handle provided by the lever arm tucks out of the way so that no portion of the lever arm protrudes above the upper surface or past any side surface of the module. This ensures that sufficient clearance is provided so that the enclosure doors can be sealed once the module is installed.

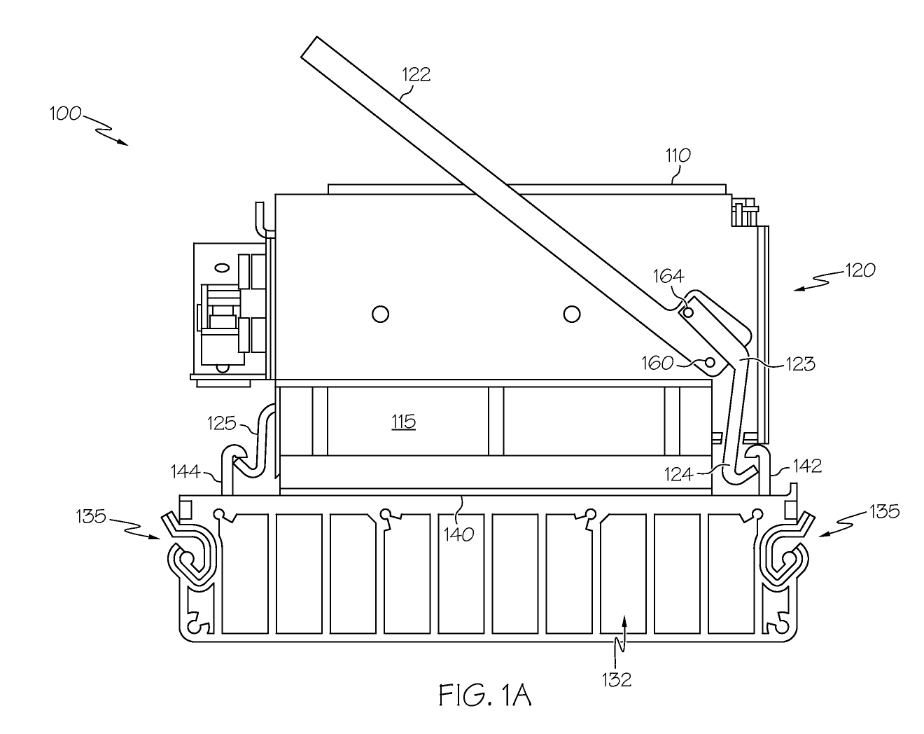

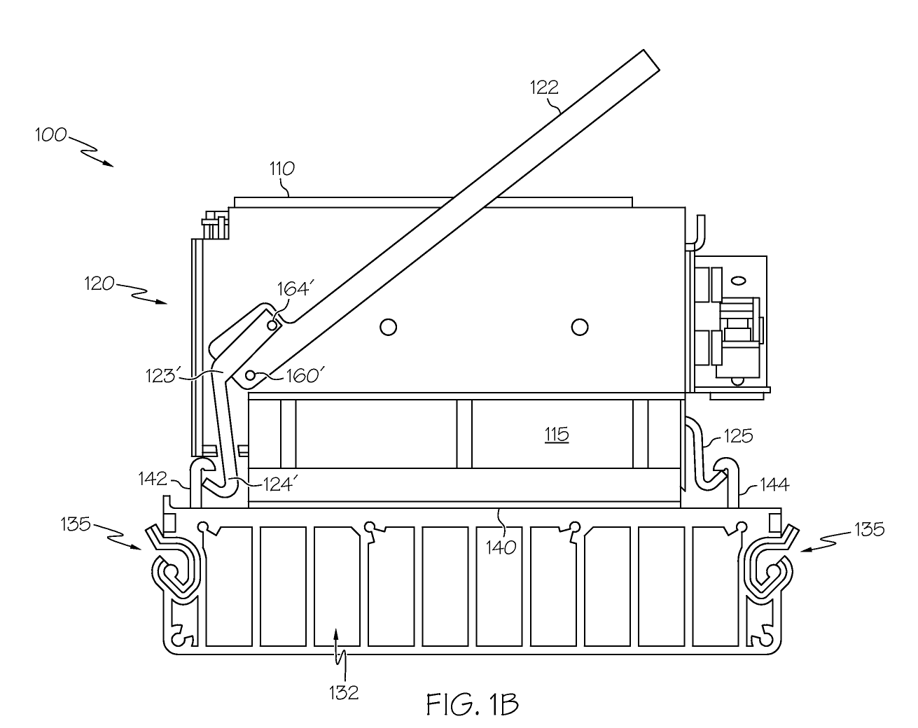

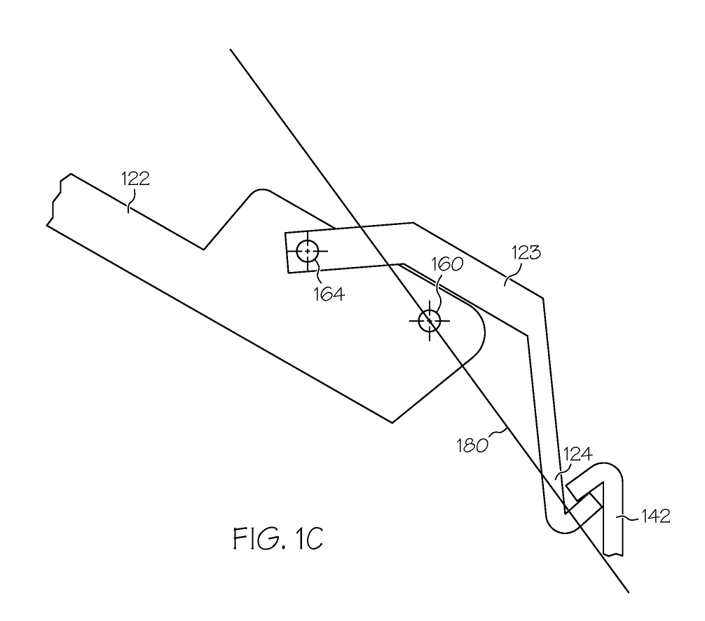

FIGS. 1A and 1B are diagrams illustrating generally at 100 an electronics module 110 having a mounting mechanism (shown generally at 120) of one embodiment of the present invention. FIG. 1A illustrates an upper (or first) side of module 110 which FIG. 1B illustrates the opposing lower (or second) side of module 110. In one embodiment, electronics module 110 comprises electrical components for implementing broad-band wireless telecommunications within a radio frequency (RF) band, based on modulation standards such as, but not limited to, Advanced Mobile Phone System (AMPS), code division multiple access (CDMA), Wide-band CDMA (WCDMA), time division multiple access (TDMA), Global System for Mobile communications (GSM), Cellular Digital Packet Data (CDPD), Enhanced Data rates for GSM Evolution (EDGE), General Packet Radio Service (GPRS), Integrated Digital Enhanced Network (iDEN), and Orthogonal Frequency Division Multiplexing (OFDM), Worldwide Interoperability for Microwave Access (WiMax), and Long Term Evolution (LTE). As such, electronics module 110 includes one or more high power electronic components 115, such as a high power RF amplifier.

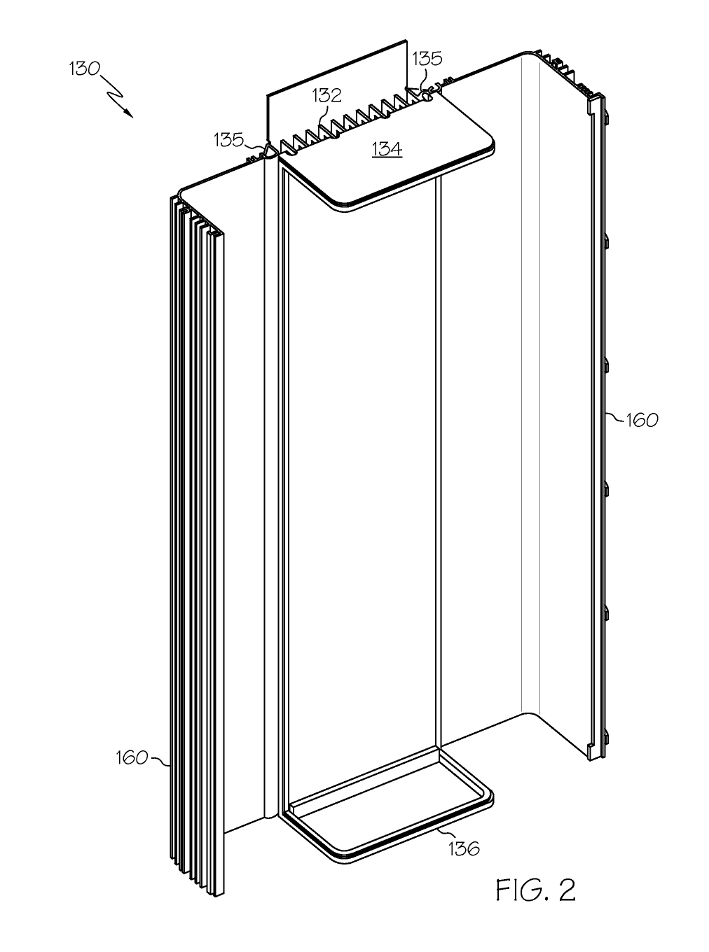

Electronics module 110 is installed within an enclosure 130, such as shown in FIG. 2. Enclosure 130 comprises a heat sink 132 that acts as a backplane for enclosure 130. Enclosure 130 further includes upper and lower panels 134 and 136 coupled to the heat sink 132, and enclosure doors 160 each attached via a respective hinge 135 to the heat sink 132. Enclosure doors 160 close to form a weatherproof seal around the upper and lower panels 134 and 136, and seal against each other, to create an enclosed environment that protects electronics module 110 from environmental elements and from tampering.

The high power electronic components 115 are located within electronics module 110 such that they either directly or indirectly establish a heat transferring interface 140 that facilitates the transfer of thermal energy generated by the components 115 to the heat sink 132. Heat sink 132, in turn, facilitates dissipation of that thermal energy to the external environment surrounding the enclosure 130. In one embodiment, the heat transferring interface 140 comprises part of the device body of the high power electronic components 115. In one embodiment, either the heat transferring interface 140 or the heat sink 132 further comprises a thermal phase-change material, or other thermally conducting material.

In order to secure electronics module 110 within enclosure 130 so that the heat transferring interface 140 of module 110 is firmly in contact with heat sink 132, the embodiment shown in FIGS. 1A and 1B provides the mounting mechanism 120. Referring to FIG. 1A, mounting mechanism 120 comprises a lever arm component 122 and a first latching arm component 123 that further comprises a latching hook 124. Module 110 further comprises a secondary fastener shown in FIGS. 1A and 1B as a hook 125. As shown in FIG. 1B, mounting mechanism 120 further comprises a second latching arm component 123′ with a latching hook 124′ that are mirror images of latching arm component 123 and latching hook 124, respectively.

Mounting mechanism 120 secures electronics module 110 onto heat sink 132 by engaging the latching hooks 124 and 124′, and secondary fastener 125, with corresponding hook mechanism 142 and 144 located on heat sink 132. In one embodiment, hook mechanism 142 and 144 are continuous extruded metal components mounted in parallel to the length of heat sink 132 from approximately upper panel 134 towards lower panel 136. In one embodiment secondary fastener 125 is also an extruded metal component running the width of module 110.

The lever arm component 122 and latching arm components 123 and 123′ are coupled together, and to the module 110 using an “over-center” dual pivot-axis configuration. The lever arm component 122 spans the width of module 110 from the first side of module 110 to the second side of module 110. The lever arm component 122 is coupled to the module 110 at pivot points 160 and 160′. The pivot points 160 and 160′ are aligned to form a first axis of rotation for lever arm component 122 about module 110. The latching arm components 123 and 123′ are each respectively coupled to the lever arm component 122 at a pivot point 164 and 164′. Pivot points 164, 164′ form a second axis or rotation that is offset from the first axis formed by pivot points 160, 160′ such that the pivot points 164, 164′ will rotate about pivot points 160, 160′ via an arced path as lever arm component 122 is operated.

In operation, electronics module 110 is installed by first engaging secondary fastener 125 into the heat sink's second hook mechanism 144. With the lever arm component 122 rotated into a disengaged position (that is, clockwise as viewed from FIG. 1A) the latching arm components 123, 123′ are free to swing. Electronics module 110 is rotated into position so that the heat transferring interface 140 is pressed flush against heat sink 132. Then, as the lever arm component 122 is rotated towards module 110 and into the engaged position, latching hooks 124, 124′ will catch the heat sink's first hook mechanism 142. As the lever arm component 122 rotates into the engaged position, each latching hook 124, 124′ will exert a force onto heat sink hook mechanism 142 which will press heat transferring interface 140 into firm contact with heat sink 132.

FIG. 1C provides a detailed view of the junction between lever arm component 122 and latching arm component 123. Once lever arm component 122 is rotated such that latching arm component 123 catches heat sink hook mechanism 142, a locking axis 180 is defined. In one embodiment, locking axis 180 is defined by the line that connects the interface of latching hook 124 and hook mechanism 142 with pivot point 160. When lever arm component 122 is engaged such that pivot point 164 crosses locking axis 180, the mounting mechanism 120 will “lock” such that it will require a non-trivial force applied to the lever arm component 122 to swing pivot point 164 clockwise back past pivot point 160. This over-center configuration of the lever arm and latching arm components 122 and 123 produces a “snapping” action as the mechanism 110 is locked, providing feedback to the installer that the latching mechanism is properly engaged.

In alternate embodiments the electronics enclosure 130 is sized to accommodate one or more additional electronics modules such as module 110. In one such embodiment, these additional modules are installed onto heat sink 132 using the same heat sink hook mechanisms 142 and 144 described above for mounting module 110.

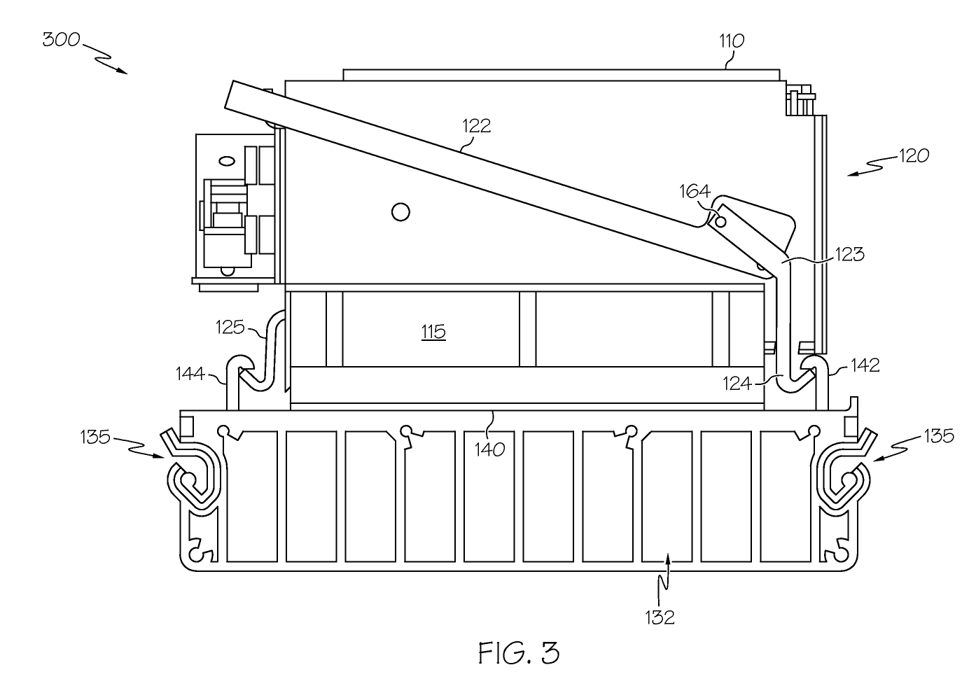

As shown in FIG. 3 generally at 300, in one embodiment, installing module 110 with the lever arm component 122 rotated into the fully engaged position also positions the lever arm component 122 within the profile of module 110 such that lever arm component will not interfere with the closing of enclosure doors 160. In one embodiment, failure to fully engage lever arm component 122 will cause a portion of the lever arm component to protrude beyond the profile of module 110 so that enclosure doors 160 cannot be secured together. This further provides feedback to the installer that the latching mechanism 120 is properly engaged.

In one embodiment, in operation, de-installation of electronics module 110 is performed by rotating the lever arm component 122 to disengage the latching mechanism 120 and rotating electronics module 110 to disengage secondary fastener 125 from heat sink hook 144. When electronics module 110 is not installed in enclosure 130, lever arm component 122 functions as a handle for holding and carrying the electronics module 110. In one embodiment, electronics module 110 weight approximately 16-18 pounds. Accordingly, in one embodiment, the hardware for implementing mounting mechanism 120 is specified to support the weight of electronics module 110 when carried by lever arm component 122.

Although specific embodiments have been illustrated and described herein, it will be appreciated by those of ordinary skill in the art that any arrangement, which is calculated to achieve the same purpose, may be substituted for the specific embodiment shown. This disclosure is intended to cover any adaptations or variations of the present invention. Therefore, it is manifestly intended that this invention be limited only by the claims and the equivalents thereof.

What is claimed is:

1. A locking mechanism for securing a module within an electronics enclosure, the mechanism comprising:
a lever arm component rotatably coupled to a first side of an electronics module and a second side of the electronics module that opposes the first side,
wherein the lever arm component rotates about a first axis that passes through the electronics module;
a first latching arm component including a first latching hook, the first latching arm component rotatably coupled to the lever arm component on the first side of the electronics module, wherein the first latching arm component rotates about a second axis that run parallel to and offset from the first axis;
a second latching arm component including a second latching hook, the second latching arm component rotatably coupled to the lever arm component on the second side of the electronics module, wherein the second latching arm component rotates about the second axis that runs parallel to and offset from the first axis; and
at least one secondary fastener coupled to the electronics module;
wherein the first axis and second axis are oriented in an over-center configuration such that when the lever arm component is rotated about the first axis from a first position to a second position, the second axis will pass through a locking axis;
wherein when the lever arm component is rotated about the first axis from the first position to the second position, the first latching hook and the second latching hook apply a force against at least a first hook mechanism of the electronics enclosure that presses the electronics module against a heat sink of the electronics enclosure.

2. The locking mechanism of claim 1, wherein the first latching hook and the second latching hook are shaped to engage at least one hook mechanism located on the heat sink of the electronics enclosure.

3. The locking mechanism of claim 1, wherein the at least one secondary fastener is shaped to engage at least one hook mechanism located on the heat sink of the electronics enclosure.

4. The locking mechanism of claim 1, wherein the at least one secondary faster is an extruded metal component running a width of the electronics module.

5. The locking mechanism of claim 1, wherein when the lever arm component is placed in the second position, the lever arm component rests in a recess of the electronics module such that no part of the lever arm component protrudes past a profile of the electronics module.

6. The locking mechanism of claim 1, wherein when the lever arm component is rotated into the first position, the lever arm functions as a handle for holding the electronics module.

7. A wireless radio electronics module with locking mechanism, the module comprising:
one or more high power electronic components;
a heat transferring interface that receives thermal energy emitted from the one or more high power electronic components;
a lever arm component rotatably coupled to a first side of the electronics module and a second side of the electronics module that opposes the first side,
wherein the lever arm component rotates about a first axis that passes through the electronics module;
a first latching arm component including a first latching hook, the first latching arm component rotatably coupled to the lever arm component on the first side of the electronics module, wherein the first latching arm component rotates about a second axis that run parallel to and offset from the first axis;
a second latching arm component including a second latching hook, the second latching arm component rotatably coupled to the lever arm component on the second side of the electronics module, wherein the second latching arm component rotates about the second axis that runs parallel to and offset from the first axis;
at least one secondary fastener coupled to the electronics module;
wherein the first axis and second axis are oriented in an over-center configuration such that when the lever arm component is rotated about the first axis from a first position to a second position, the second axis will pass through a locking axis;
wherein when the lever arm component is rotated about the first axis from the first position to the second position, the first latching hook and the second latching hook apply a force that presses the heat transferring interface against a heat sink of an electronics enclosure.

8. The module of claim 7, wherein the first latching hook and the second latching hook are shaped to engage at least one hook mechanism located on the heat sink of the electronics enclosure.

9. The module of claim 7, wherein the at least one secondary fastener is shaped to engage at least one hook mechanism located on the heat sink of the electronics enclosure.

10. The module of claim 7, wherein the at least one secondary faster is an extruded metal component running a width of the electronics module.

11. The module of claim 7, wherein when the lever arm component is placed in the second position, the lever arm component rests in a recess of the electronics module such that no part of the lever arm component protrudes past a profile of the electronics module.

12. The module of claim 7, wherein when the lever arm component is rotated into the first position, the lever arm functions as a handle for holding the electronics module.

13. A system for securing a wireless radio electronics module within an electronics enclosure, the system comprising:
a first electronics module that includes
one or more high power electronic components;
a heat transferring interface that receives thermal energy emitted from the one or more high power electronic components;
a lever arm component rotatably coupled to a first side of the electronics module and a second side of the electronics module that opposes the first side, wherein the lever arm component rotates about a first axis that passes through the electronics module;
a first latching arm component including a first latching hook, the first latching arm component rotatably coupled to the lever arm component on the first side of the electronics module, wherein the first latching arm component rotates about a second axis that run parallel to and offset from the first axis;
a second latching arm component including a second latching hook, the second latching arm component rotatably coupled to the lever arm component on the second side of the electronics module, wherein the second latching arm component rotates about the second axis that runs parallel to and offset from the first axis; and
at least one secondary fastener coupled to the electronics module;
wherein the first axis and second axis are oriented in an over-center configuration such that when the lever arm component is rotated about the first axis from a first position to a second position, the second axis will pass through a locking axis; and
an electronics enclosure that includes
a backplane that includes a heat sink;
a first hook mechanism shaped to engage the first latching hook and the second latching hook;
a second hook mechanism shaped to engage the secondary fastener; and
at least one door secured to the backplane;
wherein when the lever arm component is rotated about the first axis from the first position to the second position, the first latching hook and the second latching hook apply a force that presses the heat transferring interface against the heat sink of the electronics enclosure.

14. The system of claim 13, further comprising:
a second electronics module that includes
one or more high power electronic components;
a heat transferring interface that receives thermal energy emitted from the one or more high power electronic components;
a lever arm component rotatably coupled to a first side of the electronics module and a second side of the electronics module that opposes the first side, wherein the lever arm component rotates about a first axis that passes through the electronics module;
a first latching arm component including a first latching hook, the first latching arm component rotatably coupled to the lever arm component on the first side of the electronics module, wherein the first latching arm component rotates about a second axis that run parallel to and offset from the first axis;
a second latching arm component including a second latching hook, the second latching arm component rotatably coupled to the lever arm component on the second side of the electronics module, wherein the second latching arm component rotates about the second axis that runs parallel to and offset from the first axis; and
at least one secondary fastener coupled to the electronics module;
wherein the first axis and second axis are oriented in an over-center configuration such that when the lever arm component is rotated about the first axis from a first position to a second position, the second axis will pass through a locking axis;
wherein when the lever arm component is rotated about the first axis from the first position to the second position, the first latching hook and the second latching hook of the second electronics module apply a force that presses the heat transferring interface of the second electronics module against the heat sink of the electronics enclosure.

15. The system of claim 13, wherein the at least one secondary faster is an extruded metal component running a width of the electronics module.

16. The system of claim 13, wherein the first hook mechanism and the second hook mechanism are each extruded metal components attached to the heat sink.

17. The system of claim 13, wherein the first hook mechanism and the second hook mechanism are each extruded metal components integral to the heat sink.

18. The system of claim 13, wherein when the lever arm component is placed in the second position, the lever arm component rests in a recess of the electronics module such that no part of the lever arm component protrudes past a profile of the electronics module.

19. The system of claim 14, wherein when the lever arm component is not positioned into the recess of the electronics module, the lever arm component prevents the at least one door of the electronics enclosure from fully closing.

20. The system of claim 14, wherein when the lever arm component is rotated into the first position, the lever arm functions as a handle for holding the electronics module.
